(19) United States
(12) Patent Application Publication
(10) Pub. No.: US 2008/0121280 A1
(43) Pub. Date: May 29, 2008

(54) METHOD FOR THE PRODUCTION OF PHOTOVOLTAIC CELLS

(75) Inventors: Lodiwijk Carnel, Steenokkrezeel (BE); Ivan Gordon, Mechelen (BE); Jef Poortmans, Kessel-Lo (BE); Guy Beaucarne, Oud-Heverlee (BE)

Correspondence Address: KNOBBE MARTENS OLSON & BEAR LLP, 2040 MAIN STREET, FOURTEENTH FLOOR, IRVINE, CA, 92614, US

(73) Assignee: Interuniversitair Microelektronica Centrum (IMEC) vzw, Leuven (BE)

(21) Appl. No.: 11/941,875

(22) Filed: Nov. 16, 2007

Related U.S. Application Data
(63) Continuation of application No. PCT/EP2006/004660, filed on May 17, 2006.
(60) Provisional application No. 60/682,208, filed on May 17, 2005.

(51) Int. Cl. H01L 31/0376; H01L 31/042; H01L 31/18

(52) U.S. Cl. 136/258; 438/96; 257/E31.048

(57) ABSTRACT

A method for the production of a photovoltaic device is disclosed. In one aspect, the method comprises providing a carrier substrate. The method further comprises forming a crystalline semiconductor layer on the substrate. The method further comprises carrying out hydrogen passivation of the crystalline semiconductor layer. The method further comprises creating an emitter on the surface of the passivated crystalline semiconductor layer.

### CROSS REFERENCE TO RELATED APPLICATIONS

This application is a continuation of International Application PCT/EP2006/004660, filed on May 17, 2006, which claims priority under 35 U.S.C. §119(e) to U.S. provisional patent application 60/682,208 filed on May 17, 2005. Each of the above applications is incorporated by reference herein in its entirety.

### BACKGROUND OF THE INVENTION

1. Technical field of the Invention

The present invention relates to the field of photovoltaic cells and production methods therefor.

2. Description of the Related Technology

Thin-film polycrystalline-silicon (pc-Si) solar cells are considered to be one of the most promising alternatives to bulk silicon solar cells. Thin films significantly decrease the silicon material cost which accounts for about half of the total cost of standard silicon solar modules. Chemical vapor deposition (CVD) at temperatures above about 1000° C. offers the opportunity of combining high growth rates (e.g. >1 μm/min) with the use of cheap ceramic substrates. Attempts to make thin-film solar cells in polycrystalline-silicon layers deposited by thermal CVD on ceramic substrates have led so far only to moderate energy conversion efficiencies and low open-circuit voltages (V_{oc}), around 460 mV or below. A common feature of these devices is an n⁺ emitter created by the traditional diffusion of phosphorous at high temperature. Another possibility to create an emitter is by depositing thin amorphous silicon layers, forming a heterojunction emitter. Heterojunction solar cells can potentially lead to very high efficiency, as was demonstrated by H. Sakata, T. Nakai, T. Baba, M. Taguchi, S. Tsuge, K. Uchihashi, S. Kiyama, “20.7% highest efficiency large area (100.5 cm²) HIT cell,” presented at 28th IEEE PVSC, Anchorage, USA, 2000.

An important advantage of heterojunction emitters is that the formation of heterojunction emitters occurs at low temperature (below 400° C.) (in contrast with traditional P-diffused emitters).

Until now however, obtained efficiencies are too low to lead to a cost reduction in photovoltaics. To obtain cells with higher efficiencies, polycrystalline-silicon layers need large grains, good passivation and an optimized cell design.

### SUMMARY OF CERTAIN INVENTIVE ASPECTS

Certain inventive aspects relate to an improved or alternative method for producing photovoltaic cell and devices, which, e.g. alleviates or avoids the problems of the prior art.

A first inventive aspect relates to methods for the production of a photovoltaic device, comprising:
a. providing a carrier substrate,
b. providing, on the substrate, a crystalline semiconductor layer, for example comprising silicon, e.g. a silicon or silicon germanium layer,
c. carrying out hydrogen passivation of the crystalline semiconductor layer, and
d. creating an emitter on the surface of the passivated crystalline semiconductor layer.

Applying the hydrogen passivation before emitter formation makes the process more effective and results in better photovoltaic cells. This is when compared to the conventional method which consists of creating the emitter first, e.g. by P-diffusion, first, and afterwards applying hydrogen passivation.

The carrier substrate can be any suitable carrier substrate known to a skilled technologist such as, ceramic substrate, glass substrate, steel substrate, semiconductor substrate, e.g. silicon substrate, which may be covered by a dielectric. It can advantageously be a cheap substrate such as a ceramic substrate, a glass substrate or a glass-ceramic substrate.

The crystalline semiconductor layer may comprise silicon and may for example be a crystalline silicon layer, or a crystalline SiGe layer. The crystalline silicon layer can be a polycrystalline, multicrystalline or microcrystalline silicon layer. In Paul A. Basore, “Short Communication: Defining Terms for Crystalline Silicon Solar Cells”, Progress in Photovoltaics; Research and applications, Volume 2, 177-179 (1994), current state-of-the-art naming of crystals based on their grain sizes is given as shown in the table below, which also is the naming used for the purpose of the present description.

| Descriptor | Symbol | Grain size |
|---|---|---|
| Single-crystal | sc-Si | >10 cm |
| Multicrystalline | mc-Si | 1 mm-10 cm |
| Polycrystalline | pc-Si | 1 μm-1 mm |
| microcrystalline | μc-Si | <1 μm |

The crystalline layer can be provided by CVD or by an AIC process, or by a combination thereof. It can also be provided by solid phase crystallization of amorphous semiconductor material, e.g. amorphous silicon, by solution growth or electrodeposition.

In certain embodiments of the present invention, the emitter is a heterojunction emitter, i.e. an emitter that is made of another semiconducting material than that used in the remainder of the device, namely for example silicon. The combination of the two processes, hydrogenation and heterojunction emitter formation is advantageous in this sequence, and results in a better passivation of the polycrystalline material and hence a higher open-circuit voltage.

In certain embodiments the emitter is a homojunction emitter, i.e. the emitter is made of the same semiconducting material as is used in the remainder of the device, namely for example crystalline silicon. A homojunction emitter can for instance be achieved by depositing a layer of the same material as the layer of the crystalline layer below, on top of this crystalline layer, after passivation thereof.

The act of creating an emitter can comprise depositing at least one thin amorphous semiconductor layer, e.g. an amorphous silicon layer, on top of the passivated crystalline semiconductor layer. The deposition of the thin amorphous layer can be performed by PECVD (Plasma Enhanced Chemical Vapor Deposition), but also by hot-wire CVD, vacuum evaporation or sputtering or any other suitable method.

The deposition of the amorphous layer can be performed below about 300, 250, 200, 150 degrees Celsius. Such temperatures are sufficiently low in order to not significantly negatively impact the hydrogenation level of the crystalline semiconductor layer.

In advantageous embodiments the thin amorphous semiconductor layer forming the emitter, e.g. amorphous silicon layer, is thinner than about 50, 40, 30, 20, 10 nm. The thin amorphous layer is preferably thicker than about 0.1 or 1 nm, to avoid tunneling effect, which can jeopardize the resulting solar cell efficiency. The amorphous layer can consist of a stack of sublayers with different doping levels. Advantageously a thin intrinsic layer (thickness preferably between about 1 and 20 nm, more preferably between about 2 and 5 nm) stacked underneath an amorphous layer with an opposite doping type to that of the crystalline layer can be provided. The total thickness of the stack is preferably lower than about 100, 80, 40, 20 nm.

In certain embodiments the hydrogenation process for passivation of the crystalline semiconductor layer is performed at a temperature below about 900, or below 700, or below 500 degrees Celsius.

Open-circuit voltages (V_{oc}) were much higher for cells with the process sequence according to certain inventive aspects when compared to the conventional sequence, as described before, for silicon solar cells, reaching values up to about 520 mV. A maximum efficiency of about 5.3% was obtained. The high V_{oc} and efficiency values obtained in this work form an important milestone towards cost-effective polycrystalline-silicon solar cells.

A second inventive aspect relates to photovoltaic cells, which show a substantially lower dip in their H concentration at the level of the emitter junction than conventional photovoltaic cells.

### BRIEF DESCRIPTION OF THE DRAWINGS

FIG. 1 shows the current—voltage characteristics of two solar cells. The first one, labeled ‘diffused emitter’ was obtained by the conventional method that includes P-diffusion at high temperature to create an emitter, which is then followed by hydrogen passivation. The other device, labeled ‘heterojunction emitter’ was made with the method proposed according to embodiments of in the present invention, which includes hydrogen passivation prior to emitter formation. As can be seen from FIG. 1, the Voc of the latter device is much higher than that of the reference device.

FIG. 2 is a diagram showing external quantum efficiency (EQE) curves for the two devices of FIG. 1. The device made with the method according to embodiments of the present invention (labeled ‘heterojunction emitter’) shows a slightly better response in the short wavelength range. This might be due to the fact that the emitter is thinner, with less useless absorption in highly doped regions. At long wavelengths, the conventional device with diffused emitter shows higher response, which is believed to be linked to the phenomenon of preferential doping.

FIG. 3 is a diagram showing Suns V_{oc} measurement for the device made with the method proposed in accordance with certain embodiments (labeled ‘heterojunction emitter’) and the device made with the conventional method comprising P-diffusion and subsequent hydrogenation (labeled ‘diffused emitter’). The new method leads to a Suns Voc characteristic where the second diode component, usually associated with recombination in the depletion region, is much lower (ideality factor closer to about 1) than the conventional method.

FIG. 4 is a diagram showing D profiles, i.e. graphs showing the concentration of uncharged particles and the depth where they appear in the photovoltaic cell, measured on samples that underwent hydrogenation processes with deuterium, which has a similar behavior to that of hydrogen but which SIMS can detect with sufficient sensitivity for diffused emitter. If the diffused emitter is present during passivation, e.g. hydrogenation, passivation, e.g. hydrogenation, is not most efficient. If no diffused emitter is present during passivation, e.g. hydrogenation, as is the case in a method according to certain embodiments, the passivation, e.g. hydrogenation, is more effective as witnessed by the higher deuterium concentration in the layer.

FIG. 5 is a diagram illustrating D profiles obtained with SIMS after passivation with D plasma. Here again two profiles are illustrated: one with emitter and one without emitter.

FIG. 6 is a flowchart of an exemplary method of producing a photovoltaic device.

### DETAILED DESCRIPTION OF CERTAIN INVENTIVE EMBODIMENTS

The present invention will be described with respect to particular embodiments and with reference to certain drawings but the invention is not limited thereto. The drawings described are only schematic and are non-limiting. In the drawings, the size of some of the elements may be exaggerated and not drawn on scale for illustrative purposes.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

Both fine-grained and coarse-grained polycrystalline-silicon layers have been investigated. Both materials were deposited in a single-wafer CVD reactor (Epsilon ASM) at about 1130° C. using trichlorosilane as precursor gas. The fine-grained pc-Si layers were deposited directly on an oxidized Si wafer. In these conditions, a lot of nucleation took place in the beginning of the process, which led to small grains with an estimated average grain size of about 0.5 μm. The coarse-grained pc-Si layers on the other hand were deposited on ceramic alumina substrates (ADS996 from CoorsTek) covered by a thin pc-Si seeding layer formed by aluminum-induced crystallization (AIC). The average grain size of these layers was about 5 μm. All layers were between about 2 and 6 μm thick, and were doped with boron. The lower part of the layers was highly doped (5×1019 cm−3) to serve as a back surface field (BSF), while the top part of the layers was more lightly doped (3×1016 cm−3-1×1017 cm−3) to serve as absorber layer.

After epitaxial deposition, a heterojunction or homojunction emitter was formed on the samples. The heterojunction emitter was made by deposition of a thin layer of amorphous silicon in a direct plasma-enhanced CVD (PECVD) reactor. The depositions were done at temperatures below about 200° C. The homojunction emitter was formed by phosphorus diffusion at about 860° C. from a P-doped pyrolithic oxide, deposited by atmospheric-pressure CVD (APCVD) at about 400° C.

To passivate the grain boundaries in the layers, a post-deposition passivation process, e.g. hydrogenation process, was implemented. This passivation, e.g. hydrogenation, was done in a direct PECVD reactor at about 400° C. In solar cells with a homojunction, the passivation, e.g. hydrogenation, was carried out after emitter formation, as otherwise all the hydrogen would diffuse from the layer during the high-temperature diffusion.

In solar cells with a heterojunction however, in accordance with the one embodiment, the passivation process, e.g. hydrogenation process, was done before the deposition of the emitter, since hydrogen has a low diffusivity at about 200° C. in pc-Si and is not expected to come out during the amorphous silicon deposition.

After emitter formation and passivation, e.g. hydrogenation, a silicon nitride layer was deposited via PECVD on the homojunction samples to act as an anti-reflective coating (ARC). On the heterojunction samples indium tin oxide (ITO) was deposited by RF-sputtering in an argon atmosphere to serve as a transparent conductive oxide (TCO). This TCO layer acts both as anti-reflection coating and as conductive layer. This is desirable because the amorphous Si emitter provides no lateral conductance.

Then photolithography and wet chemical etching were used to define the active area (1 cm²) of the solar cells. The Al (base) and Ti—Pd—Ag (front) contacts were deposited by electron-beam evaporation in combination with a shadow mask or with lift-off photolithography. All cells were mesa cells with base contacts at the periphery of the cell and emitter contacts on top of the cell in a finger pattern.

Results on fine-grained polycrystalline semiconductor, e.g. silicon, layers are given hereinafter.

The fine-grained polycrystalline silicon material had a large grain boundary density, and solar cell performance is therefore expected to be low. The obtained cell results are shown in Table 1 for samples with a total layer thickness of 4 μm.

TABLE 1
Solar cell parameters for fine-grained polycrystalline layers.

| emitter | hydrogenation | J_{sc} mA/cm² | V_{oc} mV | FF % | η % |
|---|---|---|---|---|---|
| heterojunction | yes | 9.8 | 476.0 | 63.9 | 3.0 |
| heterojunction | no | 4.5 | 275.9 | 50.5 | 0.6 |
| homojunction | yes | 13.6 | 365.1 | 52.6 | 2.6 |

When no passivation, e.g. hydrogenation, was performed on the heterojunction, the current-voltage (IV) parameters were indeed very low, as expected, with a V_{oc} of only 276 mV and an efficiency of 0.6%. Hydrogenation of he homojunction led to an enormous boost of the cell performance, increasing the V_{oc} to well above 350 mV and the efficiency to above 2.5%. Furthermore, the use of a heterojunction emitter, with a passivation process before applying the emitter, led to much higher V_{oc} values (476 mV vs. 365 mV) compared to a diffused emitter although the short-circuit density (J_{sc}) is much lower (9.8 mA/cm² vs. 13.6 mA/cm²). The highest cell efficiency obtained on fine-grained pc-Si material with a heterojunction emitter applied after passivation of the crystalline semiconductor layer was about 3.0% in the example.

Results on coarse-grained polycrystalline semiconductor, e.g. silicon, layers are given hereinafter.

Due to the larger grain size, the electronic quality of this material before hydrogenation is expected to be superior to that of the fine-grained material. Solar cell results for both types of emitters are shown in Table 2 for samples with a total layer thickness of 4 μm.

TABLE 2
Solar cell parameters for coarse-grained polycrystalline
layers, obtained by plasma hydrogenation.

| emitter | hydrogenation | J_{sc} mA/cm² | V_{oc} mV | FF % | η % |
|---|---|---|---|---|---|
| heterojunction | yes | 15.8 | 483.8 | 63.1 | 4.8 |
| heterojunction | no | 9.6 | 393.6 | 60.4 | 2.3 |
| homojunction | yes | 15.2 | 430.4 | 61.6 | 4.0 |
| homojunction | no | 14.5 | 326.6 | 52.3 | 2.5 |

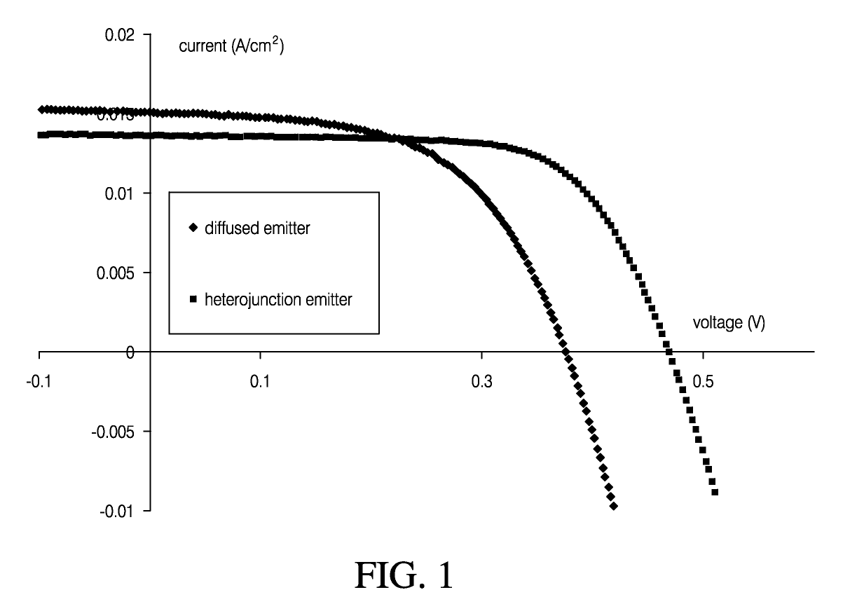

The heterojunction emitter led to much higher Voc values than the homojunction emitter, just as in the case of fine-grained polycrystalline semiconductor, e.g. silicon. With a heterojunction, the Jsc tended to be slightly lower than with a homojunction although that was not always the case. As above, where passivation, e.g. hydrogenation, has been applied to a homojunction emitter, it has been applied after emitter formation, while for a heterojunction device, it has been applied before emitter formation in accordance with certain embodiments. In FIG. 1, typical current-voltage (IV) curves are shown for two solar cells with homo- and heterojunction emitters, made on samples with exactly the same layer quality. These cells had a BSF thickness of 4 μm and an absorber thickness of 2 μm. The maximum efficiency obtained in the example with a heterojunction emitter was 5.3%, while with a diffused emitter, the maximum efficiency was 5.0%. Using Taretto's formula [see K. Taretto, U. Rau, J. H. Werner, Journal of Applied Physics, Vol. 93, No. 9, pp. 5447-5455, 2003] for the calculation of the effective diffusion length, an effective diffusion length (Leff) of 2.3 μm was obtained for the best heterojunction cell and of 0.9 μm for the best homojunction cell.

At least two interesting observations can be made concerning the hydrogenation results on coarse-grained polycrystalline silicon. First of all, the parameters J_{sc} V_{oc} and FF (fill factor) increased much more when using a heterojunction emitter formed after passivation, compared to the diffused emitter formed before passivation, where only the V_{oc} was increased significantly. A second interesting result is that before passivation, e.g. hydrogenation, the V_{oc} was already higher for the heterojunction emitter compared to the diffused emitter.

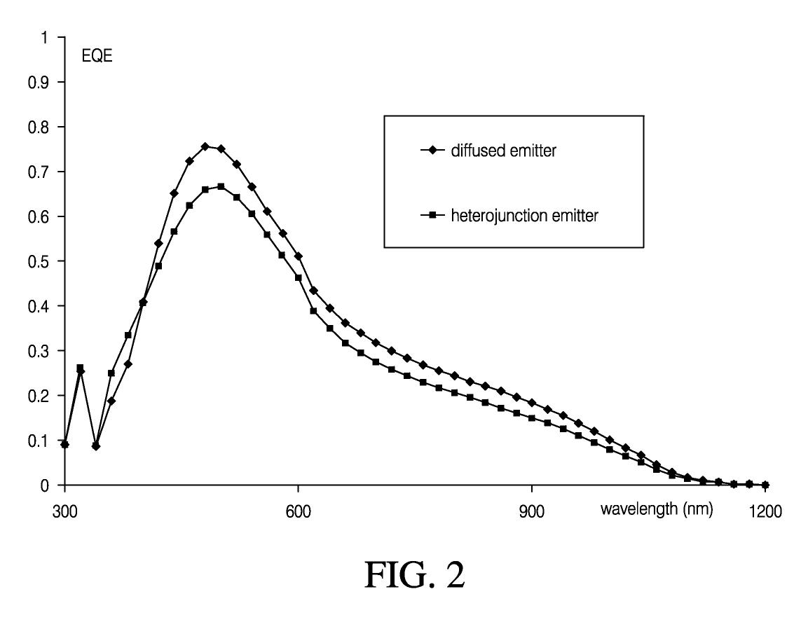

FIG. 2 compares the EQE curves of the cells presented in FIG. 1. The higher current with a diffused emitter arises from a higher collection in the long-wavelength region (400-1200 nm) of the cell. In the short wavelength region (340-400 nm) there is a higher response for the heterojunction emitter, which is due to the small thickness of the heterojunction emitter (˜8-10 nm) compared to the homojunction emitter (˜500 nm). In both curves, a hump in the IR region (700-900 nm) can be observed, which results from the high internal reflectance at the alumina substrate combined with the small diffusion length.

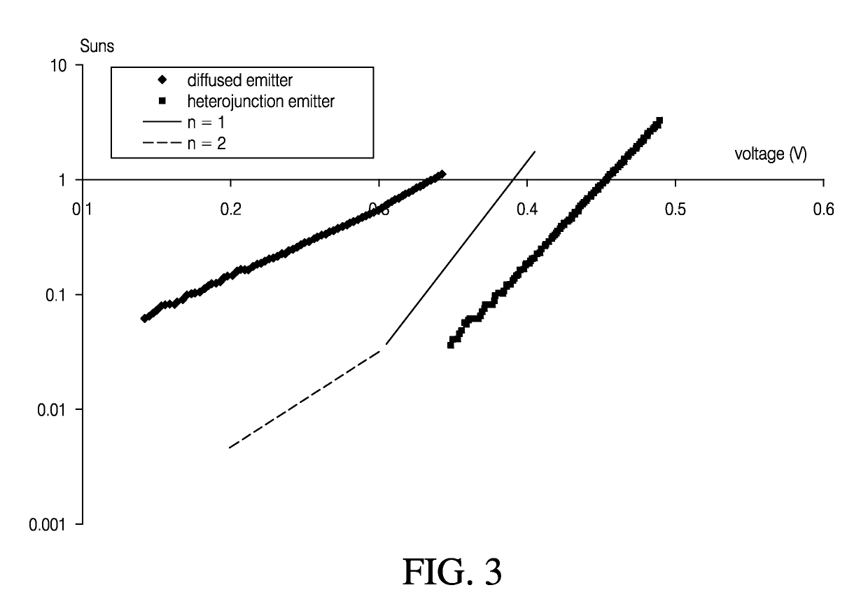

Measurement of the Suns-V_{oc} is an attractive method to determine the ideality factor n of the devices, since there is no influence of the series resistance. The plot of the logarithm of the Suns versus the voltage shows that when using a heterojunction emitter, there is a shift from ideality factors greater than 2 to an ideality factor of 1.2 (FIG. 3). This means that the heterojunction device is less determined by recombination at the junction than the homojunction device.

In Table 3, the parameters of solar cells made with very thin (0.5 μm BSF and 1.5 μm absorber) coarse-grained material are shown.

TABLE 3
Solar cell parameters for coarse-grained
polycrystalline layers with thinner layers.

| emitter | hydrogenation | J_{sc} mA/cm² | V_{oc} mV | FF % | η % |
|---|---|---|---|---|---|
| homojunction | yes | 15.3 | 458.3 | 43.7 | 3.1 |
| heterojunction | yes | 16.6 | 520.1 | 42.9 | 3.7 |

The maximum V_{oc} obtained in this example with a heterojunction emitter, passivated before emitter formation, on these samples was 520 mV, while with a diffused emitter, passivated after emitter formation, the maximum V_{oc} was only 460 mV. The calculated L_{eff} for the heterojunction cell is 4.1 μm, which is larger than the cell thickness. Such a large effective diffusion length is an important prerequisite to achieve high short-circuit currents, since the carriers can then be collected from the whole layer thickness. As a consequence, these layers also showed the highest current density (16.6 mA/cm²). However due to the thin p⁺ layer used for this samples in combination with a mesa cell structure, very high series resistances were obtained and thus low efficiencies.

### DISCUSSION

The results show that the proposed process sequence yields much higher V_{oc} values, while J_{sc} either decreases or increases slightly depending on the sample parameters.

At open circuit, the diode current precisely compensates the photogenerated current. In a two-diode model, this is described by the following expression:

$${J}_{ph} = {J}_{01} [ exp ( \frac{{qV}_{oc}}{kT} ) - 1 ] + {J}_{02} [ exp ( \frac{{qV}_{oc}}{2 kT} ) - 1 ] \qquad eq . 1$$

where J₀₁ is the saturation current density for the recombination components taking place in the quasi-neutral regions and J₀₂ is the saturation current density, associated to recombination taking place in the space charge region. The ‘−1’ in both terms on the right hand side are negligible compared to the exponential components.

In the devices of the type relates to certain embodiments, the contribution of the emitter to the first diode current is expected to be very small and can be neglected. Introducing the relevant expressions for J₀₁ and J₀₂, one obtains:

$${J}_{ph} = q \frac{{n}_{i}^{2} {D}_{n}}{{N}_{A} {L}_{eff}} exp ( \frac{{qV}_{oc}}{kT} ) + q \frac{{n}_{i} {W}_{MR}}{τ} exp ( \frac{{qV}_{oc}}{2 kT} ) \qquad eq . 2$$

where nᵢ is the intrinsic carrier concentration, Nₐ the doping density of the base, Dₙ the diffusion constant of the electrons, W_{MR} the width of the zone of maximal recombination and τ the lifetime of the minority carriers. It is not possible to solve this equation analytically to V_{oc}, but it is clear that higher pre-exponential factors lead to a lower V_{oc}.

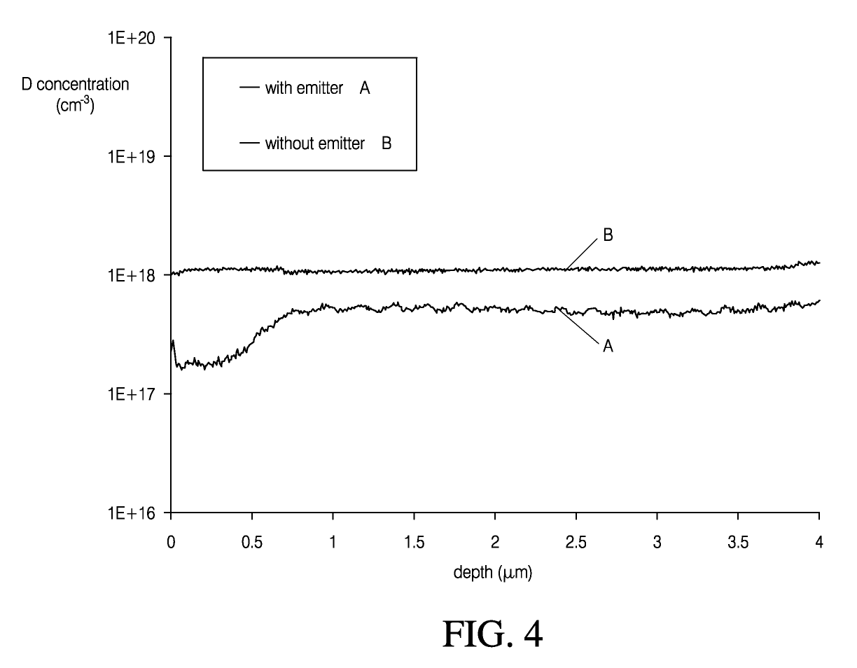

The parameters that might differ between the two types of devices have been considered. If for some reason, the doping level in the base were higher in the case of the heterojunction device, this could be an explanation for the higher V_{oc} values. However, the starting layers are identical and resistivity profile measurements on complete solar cell structures have indicated that dopant activation is about 100%. Another factor is the minority carrier lifetime. If the lifetime is higher in heterojunction devices, this implies both higher τ and L_{eff}, leading to higher V_{oc} values. This can possibly be caused by a more efficient passivation, e.g. hydrogenation, in the case of the heterojunction device. A highly doped region can hinder the diffusion of hydrogen, as the diffusivity of hydrogen in silicon is lower in such layers. As the homojunction process requires that the diffused emitter is already present at the passivation, e.g. hydrogenation, stage, a barrier for effective hydrogenation is always present when the samples are to be hydrogenated. In FIG. 4 the SIMS results are shown of the D profile, i.e. graph of concentration of uncharged particles in function of depth in the photovoltaic cell, in fine-grained pc-Si respectively with (graph A) and without a diffused P-emitter (graph B) during the passivation with a SiN:H firing process. D is used instead of H since it is easily traceable with SIMS. The presence of a highly doped region clearly leads to a dip in the D profile at the junction and to a markedly lower concentration deeper in the base when passivation is carried out with the emitter being present (graph A). The dip at the junction is probably due to the influence of the electric field at the junction on the H ions. The higher D concentration in case of no emitter being present during passivation results in a higher lifetime τ of the layers in the case of a heterojunction. Due to this better hydrogenation effect the higher V_{oc} values with heterojunction cells could be explained.

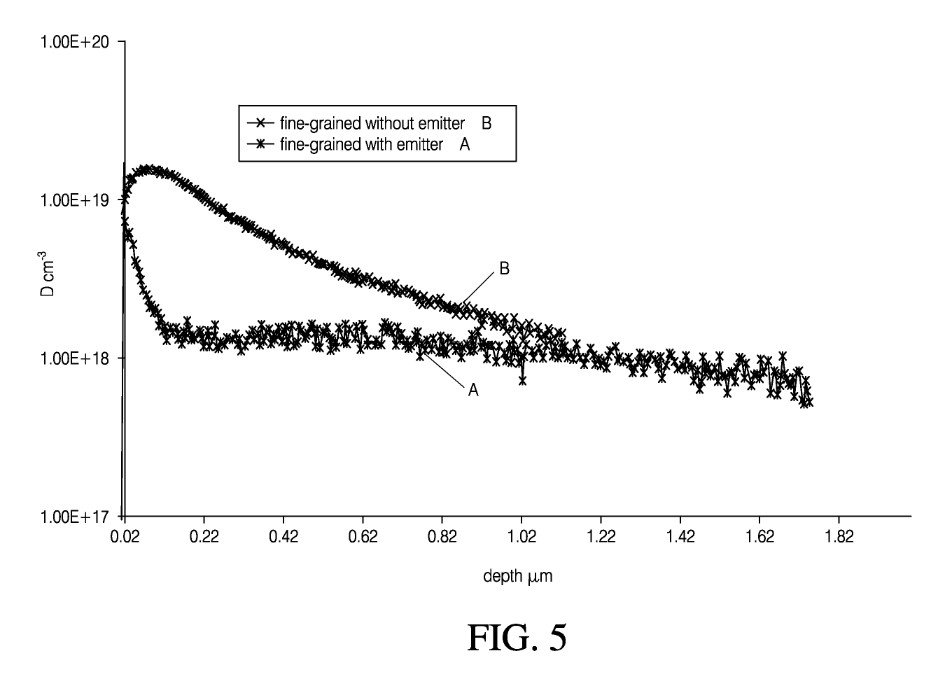

FIG. 5 illustrates D profiles obtained with SIMS after passivation with deuterium (D) plasma. Also here two profiles are shown: one with emitter (graph A) and one without emitter being present (graph B) when performing the passivation. From these SIMS profiles it can be seen that also with H⁺ plasma passivation a clear barrier is present for the D atoms to enter the substrates.

Plasma hydrogenation has been applied for a long time for crystalline silicon solar cells. The plasma hydrogenation process can be done in a remote or a direct plasma configuration. In the remote set-up, the plasma is created away from the surface resulting in a lower surface damage. In the direct plasma set-up the sample is put on one of the electrodes resulting in a higher surface damage. It was first proposed for the improvement of multicrystalline silicon, although nowadays hydrogenation through firing of a PECVD silicon nitride is considered a better solution. There, a thin amorphous silicon nitride layer is deposited on the substrate at temperatures between about 300 and 500° C. This layer contains a lot of hydrogen atoms, which are liberated to diffuse through the substrate during a subsequent rapid thermal anneal process. However, for very defect rich materials, a separate plasma hydrogenation appears to be crucial, since then a larger hydrogen concentration is absorbed in the layer (see SIMS profiles). Fine-grained polycrystalline silicon, with an even higher defect concentration, reacts even more favorably to such a treatment.

D plasma is a state in which deuterium (D) is in an ionized or radicalized form, such as e.g. D+. A D atom is a non-charged particle, thus not an ion. D is used because this easily copies H chemistry and is easily detectable with SIMS. A H₂ molecule can also be introduced into a plasma that thus results in H+ ions or a H+ plasma.

In Table 4 are shown the parameters of solar cells with SiN:H passivation on cell-level with both emitters (heterojunction according to embodiments of the present invention and diffused homojunction applied before passivation) with fine-grained poly.

TABLE 4

| Emitter | Passivation | J_{sc} | V_{oc} | Efficiency |
|---|---|---|---|---|
| Heterojunction | H⁺ plasma | 9.31 | 440.8 | 2.78 |
| | SiN:H | 8.07 | 377.1 | 1.85 |
| Homojunction | H⁺ plasma | 11.92 | 344.9 | 1.67 |
| | SiN:H | 11.65 | 355.2 | 1.55 |

Again, it can be observed that also with SiN:H passivation, a higher V_{oc} is obtained with a heterojunction emitter in accordance with embodiments of the present invention than with a diffused homojunction emitter applied before passivation, just like in the case of a H+plasma passivation.

### CONCLUSION

With the proposed process sequence, i.e. applying passivation before applying the emitter, poly silicon solar cells were obtained with an open-circuit voltage of about 520 mV on polycrystalline-silicon layers deposited on a ceramic substrate. The proposed process sequence always led to higher V_{oc}'s than devices made with the conventional diffused emitter and passivation process sequence. It is believed that this is caused by a more efficient hydrogenation and a lower recombination in the space charge region. An open-circuit voltage of 520 mV is the highest result ever for pc-Si solar cells on ceramic substrates where no remelting of the silicon is involved. This result clearly shows the high potential of such pc-Si layers for future use in solar cells applications.

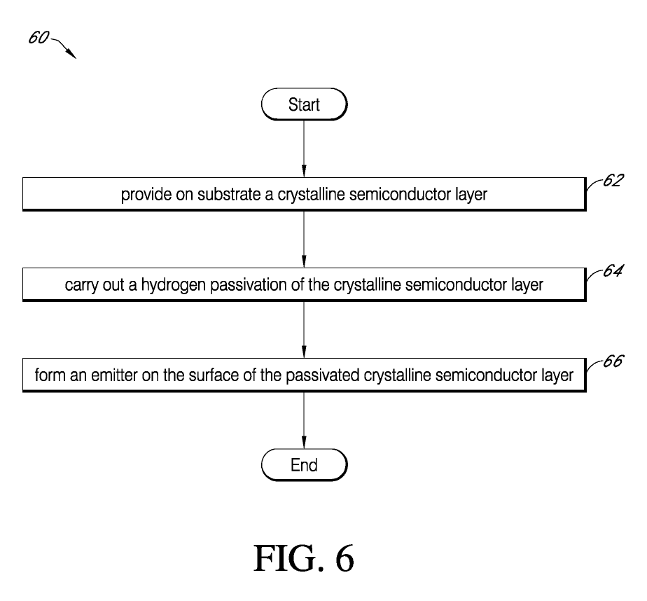

FIG. 6 is a flowchart of an exemplary method of producing a photovoltaic device. Depending on the embodiment, the process to be carried out in certain blocks of the method may be removed, merged together, or rearranged in order.

The method 60 begins at a block 62, wherein a crystalline semiconductor layer is provided on a carrier substrate. The semiconductor layer may comprise, e.g., silicon. In one embodiment, the semiconductor layer comprises a silicon layer or a silicon germanium layer. Next at a block 64, a hydrogen passivation is carried out on the crystalline semiconductor layer. Moving to a block 66, an emitter is created on the surface of the passivated crystalline semiconductor layer. As described above, the hydrogen passivation is applied before emitter formation in this method.

The foregoing description details certain embodiments of the invention. It will be appreciated, however, that no matter how detailed the foregoing appears in text, the invention may be practiced in many ways. It should be noted that the use of particular terminology when describing certain features or aspects of the invention should not be taken to imply that the terminology is being re-defined herein to be restricted to including any specific characteristics of the features or aspects of the invention with which that terminology is associated.

While the above detailed description has shown, described, and pointed out novel features of the invention as applied to various embodiments, it will be understood that various omissions, substitutions, and changes in the form and details of the device or process illustrated may be made by those skilled in the technology without departing from the spirit of the invention. The scope of the invention is indicated by the appended claims rather than by the foregoing description. All changes which come within the meaning and range of equivalency of the claims are to be embraced within their scope.

What is claimed is:

1. A method of producing a photovoltaic device, comprising:
a. forming substrate a crystalline semiconductor layer on a carrier substrate;
b. carrying out a hydrogen passivation of the crystalline semiconductor layer; and
c. forming an emitter on the surface of the passivated crystalline semiconductor layer.

2. The method according to claim 1, wherein the crystalline semiconductor layer provided on the carrier substrate comprises silicon.

3. The method according to claim 1, wherein the forming of an emitter is performed under a low temperature below about 400° C.

4. The method according to claim 1, wherein the forming of the crystalline semiconductor layer is by chemical vapor deposition (CVD) or by an aluminum-induced crystallization (AlC) process, or by a combination thereof.

5. The method according to claim 1, wherein the forming of the crystalline semiconductor layer is by solid phase crystallization of amorphous semiconductor material, by solution growth or by electrodeposition.

6. The method according to claim 3, wherein the emitter is a heterojunction.

7. The method according to claim 1, wherein the emitter is a homojunction.

8. The method according to claim 1, wherein the forming of an emitter comprises depositing at least one amorphous semiconductor layer on top of the crystalline semiconductor layer.

9. The method according to claim 8, wherein the depositing of the at least one amorphous semiconductor layer is by plasma enhanced chemical vapor deposition (PECVD), by hot-wire CVD, by vacuum evaporation or by sputtering.

10. The method according to claim 8, wherein the depositing of the amorphous semiconductor layer is at temperatures below about 300° C.

11. The method according to claim 8, wherein the depositing of at least one amorphous semiconductor layer comprises depositing an amorphous semiconductor layer with a thickness approximately between 0.1 nm and 50 nm.

12. The method according to claim 8, wherein the depositing of at least one amorphous semiconductor layer comprises depositing a stack of sub-layers.

13. The method according to claim 12, wherein at least two layers of the stack of sub-layers have different doping levels.

14. The method according to claim 8, further comprising forming an intrinsic layer between the amorphous semiconductor layer and the crystalline semiconductor layer.

15. The method according to claim 14, wherein the intrinsic layer has a thickness between approximately 1 nm and 20 nm.

16. The method according to claim 14, wherein the intrinsic layer has a doping type different from the doping type of the crystalline semiconductor layer.

17. The method according to claim 1, wherein the carrying out of a hydrogen passivation of the crystalline semiconductor layer is at a temperature below about 900° C.

18. A photovoltaic device manufactured by the method according to claim 1.
